(19) United States
(12) Patent Application Publication
(10) Pub. No.: US 2012/0299074 A1
(43) Pub. Date: Nov. 29, 2012

(54) SEMICONDUCTOR DEVICE

(75) Inventors: Atsushi HIROSE, Isehara (JP); Hidekazu MIYAIRI, Atsugi (JP); Yoshitaka YAMAMOTO, Osaka (JP); Tomohiro KIMURA, Osaka (JP)

(73) Assignees: SHARP KABUSHIKI KAISHA, Osaka (JP); SEMICONDUCTOR ENERGY LABORATORY CO., LTD., Atsugi-shi (JP)

(21) Appl. No.: 13/477,334

(22) Filed: May 22, 2012

(30) Foreign Application Priority Data
May 24, 2011 (JP) 2011-116174

(51) Int. Cl. H01L 27/06

(52) U.S. Cl. 257/300; 257/E27.016

(57) ABSTRACT

A semiconductor device in which light leakage due to misalignment is prevented even when a black matrix layer is not expanded to a designed value or more is provided. In a semiconductor device including a dual-gate thin film transistor in which a semiconductor layer is sandwiched between a bottom gate electrode and a top gate electrode, the top gate electrode is formed of a first black matrix layer, and the top gate electrode overlaps with the semiconductor layer.

### BACKGROUND OF THE INVENTION

1. Field of the Invention

The present invention relates to a semiconductor device, a liquid crystal display device, and the like. Note that in this specification, a semiconductor device refers to a semiconductor element itself or a device including a semiconductor element. As an example of such a semiconductor element, for example, a transistor (a thin film transistor or the like) can be given. In addition, a semiconductor device also refers to a display device such as a liquid crystal display device.

2. Description of the Related Art

A conventional liquid crystal display device has a structure in which a liquid crystal layer including a liquid crystal material is sandwiched between a substrate including a thin film transistor (also referred to as a thin film transistor (TFT) substrate) and a counter substrate. The TFT substrate has a layered structure in which a glass substrate, a base insulating film, a gate electrode, a gate insulating film, a semiconductor layer, source and drain electrodes, an interlayer insulating film, a pixel electrode, and an orientation film are stacked in this order, for example. The counter substrate has a layered structure in which a glass substrate, a black matrix layer (an organic resin or metal), a color filter, a counter electrode, and an orientation film are stacked in this order.

In order to prevent a thin film transistor provided in a pixel portion on the TFT substrate from being irradiated with light from a backlight or light from the outside, in the liquid crystal display device, the black matrix layer is provided in a region of the counter substrate which overlaps with the thin film transistor.

In addition, in order to improve image quality, in the conventional liquid crystal display device, a black matrix layer is also provided in a region of the counter substrate, which is over a region of the TFT substrate where projections and depressions due to a variety of metal wirings, a storage capacitor, or the like exist.

However, in the case where the black matrix layer is provided in the counter substrate, there is a problem in that light leakage occurs due to misplacement or misalignment between the counter substrate and the TFT substrate, so that the thin film transistor of the TFT substrate is irradiated with the light.

In addition, when the width of the black matrix layer is extended to a designed value or more in the counter substrate in order to prevent light leakage even if misalignment between the counter substrate and the TFT substrate occurs, the aperture ratio of the pixel portion might be reduced.

### REFERENCE

### Patent Document

[Patent Document 1] Japanese Published Patent Application No. 2008-268923

### SUMMARY OF THE INVENTION

An object of one embodiment of the present invention is to provide a semiconductor device in which light leakage due to misalignment is prevented even when a black matrix layer is not expanded to a designed value or more.

One embodiment of the present invention is a semiconductor device including a dual-gate thin film transistor including a bottom gate electrode, a top gate electrode, and a first semiconductor layer provided between the bottom gate electrode and the top gate electrode. The top gate electrode is formed of a first black matrix layer, the top gate electrode overlaps with the first semiconductor layer, and the bottom gate electrode is electrically connected to the top gate electrode. Note that the bottom gate electrode is a gate electrode provided between a substrate and the first semiconductor layer, and the top gate electrode is a gate electrode provided on the opposite side to the bottom gate electrode with respect to the first semiconductor layer.

In one embodiment of the present invention, the thin film transistor may include a source electrode and a drain electrode covering part of the first semiconductor layer.

In one embodiment of the present invention, the bottom gate electrode may be formed of a conductive film which has a larger area than the first semiconductor layer.

In one embodiment of the present invention, a second black matrix layer may be included. The second black matrix layer may be formed so as to surround the top gate electrode, electrically isolated from the top gate electrode, and formed using the same layer as the first black matrix layer.

In one embodiment of the present invention, a first capacitor including a first capacitor electrode, a first insulating film, and a second capacitor electrode; and a second capacitor including the second capacitor electrode, a second insulating film, and a third capacitor electrode may be included. The first capacitor and the second capacitor may overlap with each other, the first capacitor electrode and the third capacitor electrode may be electrically connected to each other, the first capacitor electrode may be formed using the same layer as the bottom gate electrode, and the third capacitor electrode may be formed of a third black matrix layer which is formed using the same layer as the first black matrix layer.

In one embodiment of the present invention, the second black matrix layer may be formed so as to surround the third capacitor electrode, and the second black matrix layer may be electrically isolated from the third capacitor electrode.

In one embodiment of the present invention, a first wiring electrically connected to the third capacitor electrode and a second wiring electrically connected to the source electrode or the drain electrode of the thin film transistor may be included. A second semiconductor layer may be located in an intersection portion of the first wiring and the second wiring, the first wiring may be formed using the same layer as the bottom gate electrode layer, the second wiring may be formed using the same layer as the source electrode and the drain electrode, and the second semiconductor layer may be formed using the same layer as the first semiconductor layer.

One embodiment of the present invention is a semiconductor device including a dual-gate thin film transistor including: a bottom gate electrode; a first insulating film formed over the bottom gate electrode; a first semiconductor layer formed over the first insulating film; a second insulating film formed over the first semiconductor layer; and a top gate electrode which is formed over the second insulating film and formed of a first black matrix layer, and a second black matrix layer formed over the second insulating film. The top gate electrode overlaps with the first semiconductor layer, the second black matrix layer is formed so as to surround the top gate electrode and electrically isolated from the top gate electrode, and the bottom gate electrode is electrically connected to the top gate electrode.

In one embodiment of the present invention, a source electrode and a drain electrode covering part of the first semiconductor layer may be included. The source electrode and the drain electrode may be formed over the first semiconductor layer and the first insulating film, and below the second insulating film.

In one embodiment of the present invention, a first capacitor including a first capacitor electrode, the first insulating film, and a second capacitor electrode; and a second capacitor including the second capacitor electrode, the second insulating film, and a third capacitor electrode may be included. The first capacitor and the second capacitor may overlap with each other, the first capacitor electrode and the third capacitor electrode may be electrically connected to each other, the first capacitor electrode may be formed using the same layer as the bottom gate electrode, the third capacitor electrode may be formed of a third black matrix layer which is formed using the same layer as the first black matrix layer, and the second black matrix layer may be formed so as to surround the third capacitor electrode and electrically isolated from the third capacitor electrode.

In one embodiment of the present invention a first wiring electrically connected to the third capacitor electrode and a second wiring electrically connected to the source electrode or the drain electrode of the thin film transistor may be included. The first insulating film, a second semiconductor layer, and the second insulating film may be located in an intersection portion of the first wiring and the second wiring; the first wiring may be formed using the same layer as the bottom gate electrode; and the second wiring may be formed of a fourth black matrix layer which is formed using the same layer as the first black matrix layer.

In one embodiment of the present invention, the first wiring may be a scan signal line, and the second wiring may be a video signal line.

According to one embodiment of the present invention, light leakage due to misalignment can be prevented even when a black matrix layer is not expanded to a designed value or more.

### BRIEF DESCRIPTION OF THE DRAWINGS

In the accompanying drawings:

FIG. 1 is a plan view illustrating a TFT substrate of a liquid crystal display device according to one embodiment of the present invention;

FIG. 2 is a cross-sectional view taken along line a-a′ in FIG. 1;

FIG. 3 is a cross-sectional view taken alone line b-b′ in FIG. 1;

FIG. 4 is a cross-sectional view taken along line e-e′ in FIG. 1;

FIG. 5 is a cross-sectional view taken along line f-f′ in FIG. 1;

FIG. 6 is a cross-sectional view taken along line g-g′ in FIG. 1;

FIG. 7A is a cross-sectional view illustrating a thin film transistor in which a semiconductor layer 14 includes a microcrystalline silicon region 14a and an amorphous silicon region 14b, FIG. 7B is a cross-sectional view illustrating a thin film transistor in which a semiconductor layer 14 includes a microcrystalline silicon region 14a and a pair of amorphous silicon regions 14c, and FIGS. 7C and 7D are enlarged views each illustrating a portion between an insulating film 13 and a source electrode 15a in FIG. 2;

FIG. 8 is a plan view illustrating a TFT substrate of a liquid crystal display device according to one embodiment of the present invention;

FIG. 9 is a cross-sectional view taken along line c-c′ in FIG. 8;

FIG. 10 is a cross-sectional view taken along line d-d′ in FIG. 8; and

FIG. 11 is a plan view illustrating a TFT substrate of a liquid crystal display device according to one embodiment of the present invention.

### DETAILED DESCRIPTION OF THE INVENTION

Hereinafter, embodiments of the present invention will be described in detail with reference to the drawings. However, the present invention is not limited to the following description and it is easily understood by those skilled in the art that the mode and details can be variously changed without departing from the scope and spirit of the present invention. Therefore, the present invention should not be construed as being limited to the description in the following embodiments.

### Embodiment 1

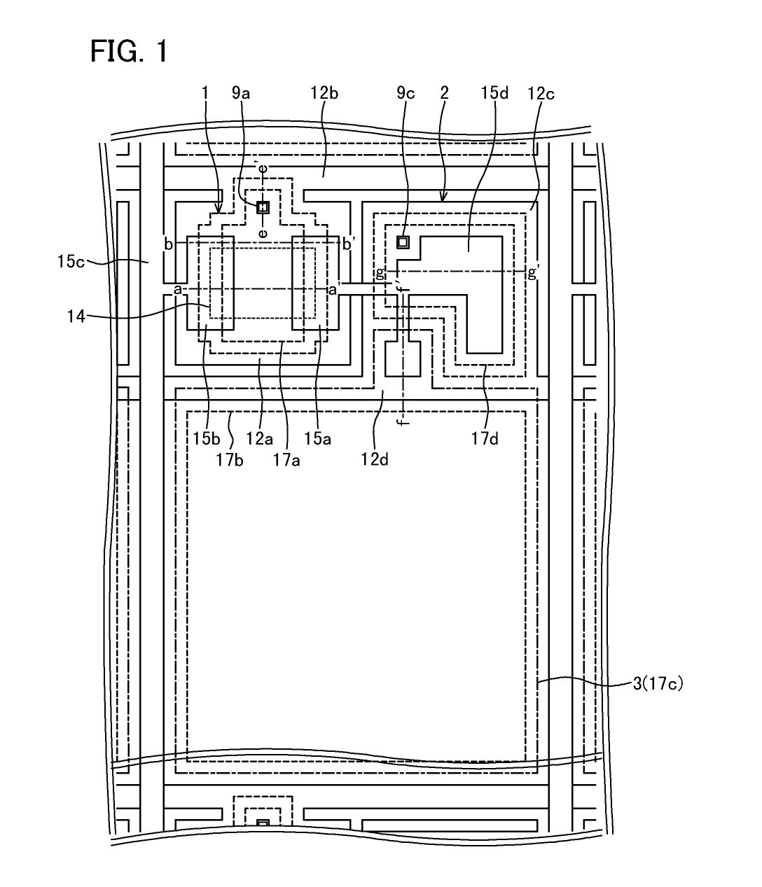

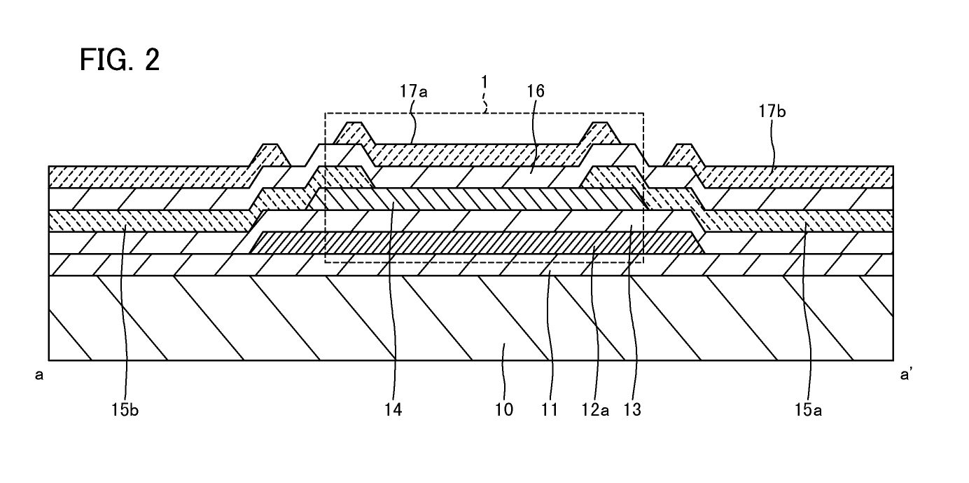

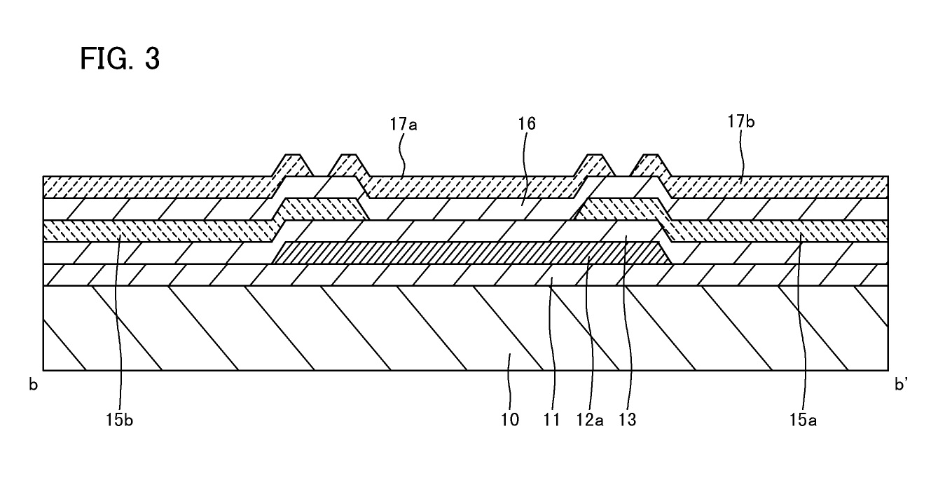

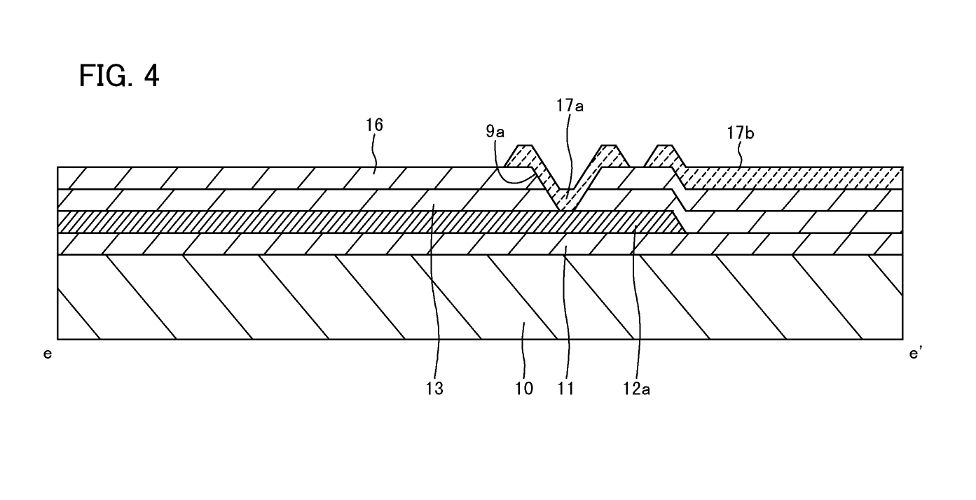

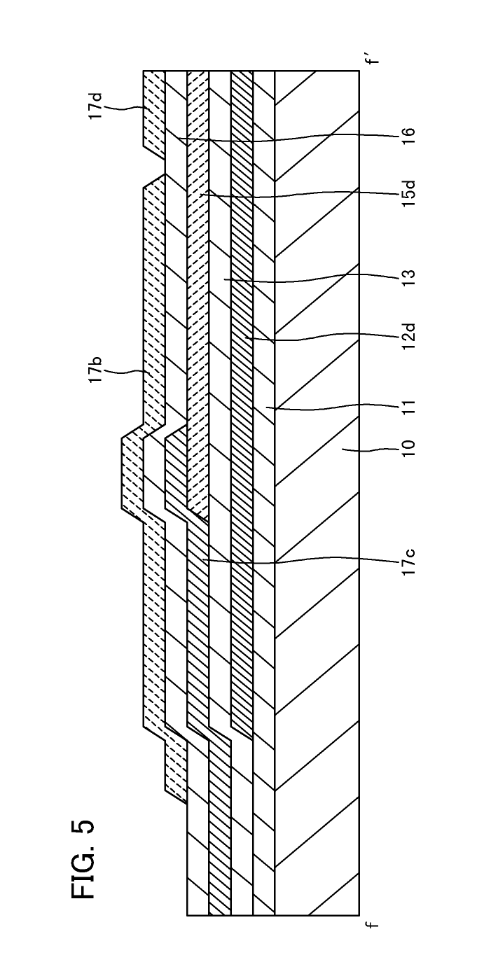

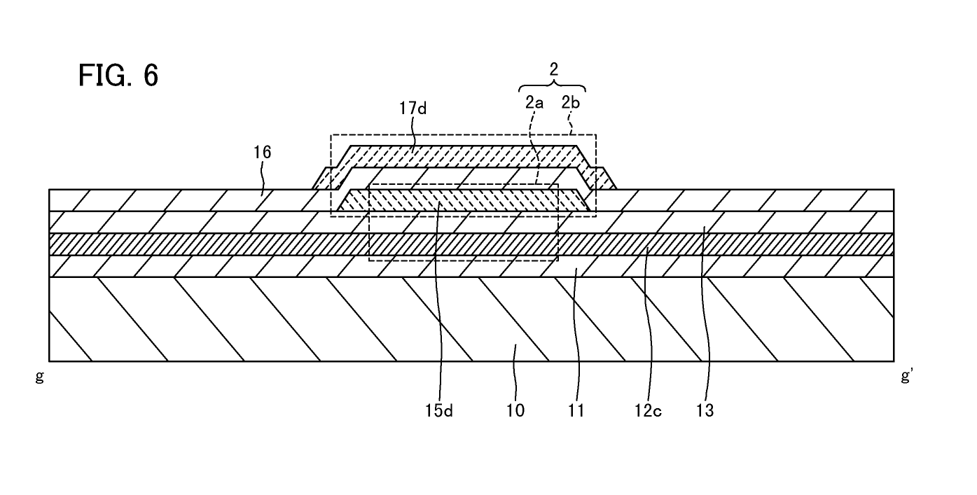

A liquid crystal display device according to one embodiment of the present invention will be described with reference to FIG. 1, FIG. 2, FIG. 3, FIG. 4, FIG. 5, and FIG. 6.

The liquid crystal display device according to one embodiment of the present invention has a structure in which a liquid crystal layer including a liquid crystal material is sandwiched between a TFT substrate and a counter substrate. The TFT substrate illustrated in FIG. 1, FIG. 2, FIG. 3, FIG. 4, FIG. 5, and FIG. 6 has a layered structure in which a glass substrate, a base film, a gate electrode, a gate insulating film, a semiconductor layer, source and drain electrodes, a light-transmitting electrode, an interlayer insulating film, a black matrix layer, and an orientation film are stacked in this order. The black matrix layer is provided on the TFT substrate side that is a backlight side, as described above, whereby light from the backlight can be efficiently blocked and light leakage due to misalignment can be reduced. The counter substrate has a layered structure in which a glass substrate, a coloring film, a protective film, a counter electrode, and an orientation film are stacked in this order. Note that although the glass substrate is used as a substrate in this embodiment, another substrate, e.g., a ceramic substrate can be used alternatively.

The TFT substrate illustrated in FIG. 1 includes a thin film transistor 1, a storage capacitor 2, and a pixel electrode 3. As illustrated in FIG. 2, FIG. 3, and FIG. 4, the thin film transistor 1 is formed over a glass substrate 10 provided with a base film 11. Note that the base film 11 is not necessarily provided, and the glass substrate 10 without the base film 11 may be used.

Specific description is given below. A bottom gate electrode 12a and a wiring 12b are formed over the base film 11. The bottom gate electrode 12a and the wiring 12b are formed of a first conductive film. An insulating film 13 is formed over the bottom gate electrode 12a, the wiring 12b, and the base film 11. A semiconductor layer 14 is formed over the insulating film 13. A source electrode 15a and a drain electrode 15b are formed over the semiconductor layer 14 and the insulating film 13. The source electrode 15a and the drain electrode 15b are formed of a second conductive film. The bottom gate electrode 12a has substantially the same thickness as the source electrode 15a and the drain electrode 15b. In the case where the bottom gate electrode 12a has a three-layer structure, the thicknesses of the three layers are 50 nm, 100 nm to 300 nm, and 50 nm, for example. A wiring 15c is formed over the insulating film 13. The wiring 15c is formed of the second conductive film. An insulating film 16 is formed over the source electrode 15a, the drain electrode 15b, the semiconductor layer 14 that is positioned between the source electrode 15a and the drain electrode 15b, and the insulating film 13. A top gate electrode 17a which is formed of a first black matrix layer is formed over the semiconductor layer 14 and the insulating film 16. In addition, a second black matrix layer 17b is formed over the insulating film 16 so as to surround the top gate electrode 17a (see FIG. 1). The second black matrix layer 17b is electrically isolated from the top gate electrode 17a. The first black matrix layer and the second black matrix layer 17b are formed using the same layer. A contact hole 9a is formed in the insulating films 13 and 16 as illustrated in FIG. 4. The top gate electrode 17a is electrically connected to the bottom gate electrode 12a through the contact hole 9a. Note that the insulating films 13 and 16, which are positioned below and over the semiconductor layer 14, respectively, serve as gate insulating films. In addition, the bottom gate electrode 12a and the wiring 12b are formed of the same first conductive film. The drain electrode 15b and the wiring 15c are formed of the same second conductive film.

As illustrated in FIG. 2, the semiconductor layer 14 of the thin film transistor has a smaller area than the bottom gate electrode 12a and is covered with the top gate electrode 17a, the source electrode 15a, and the drain electrode 15b. As illustrated in FIG. 3, the source electrode 15a and the drain electrode 15b are formed over the insulating film 13 on the outside of the semiconductor layer 14.

As illustrated in FIG. 1 and FIG. 2, the source electrode 15a, the drain electrode 15b, and the bottom gate electrode 12a can be seen in a region between the top gate electrode 17a and the second black matrix layer 17b through the insulating films 13 and 16. In order to reduce the glare of the liquid crystal display device, the region that is seen through the insulating films 13 and 16 is preferably subjected to surface modification treatment, thereby reducing reflectivity. Accordingly, reflection light which is not intended can be reduced.

The bottom gate electrode 12a is connected to the top gate electrode 17a. In other words, the top gate electrode 17a and the bottom gate electrode 12a are connected to each other through the contact hole 9a formed in the insulating films 13 and 16. In this case, a potential applied to the bottom gate electrode 12a is equal to a potential applied to the top gate electrode 17a. As a result, in the semiconductor layer 14, regions in which carriers flow, i.e., channel regions are formed on the insulating film 13 side and the insulating film 16 side; thus, the on-state current of the thin film transistor can be increased.

The storage capacitor 2 and the pixel electrode 3 are formed over the glass substrate 10 provided with the base film 11 as illustrated in FIG. 5 and FIG. 6.

Specific description is given below. A first capacitor electrode 12c and a wiring 12d are formed over the base film 11. The first capacitor electrode 12c and the wiring 12d are formed of the first conductive film. The insulating film 13 is formed over the first capacitor electrode 12c, the wiring 12d, and the base film 11. A second capacitor electrode 15d is formed over the insulating film 13. The second capacitor electrode 15d is formed of the second conductive film. A light-transmitting electrode 17c is formed as the pixel electrode 3 over the second capacitor electrode 15d and the insulating film 13. The light-transmitting electrode 17c is electrically connected to the second capacitor electrode 15d. The insulating film 16 is formed over the insulating film 13, the second capacitor electrode 15d, and the light-transmitting electrode 17c. As illustrated in FIG. 6, a third capacitor electrode 17d which is formed of a third black matrix layer is formed over the insulating film 16, and the second black matrix layer 17b is formed over the insulating film 16 so as to surround the third capacitor electrode 17d (see FIG. 1). The second black matrix layer 17b is electrically isolated from the third capacitor electrode 17d. The third black matrix layer and the second black matrix layer 17b are formed using the same layer. In addition, the second black matrix layer 17b is formed over part of the light-transmitting electrode 17c and the insulating film 16 (see FIG. 5). Further, the third capacitor electrode 17d and the first capacitor electrode 12c illustrated in FIG. 6 are electrically connected to each other through a contact hole 9c illustrated in FIG. 1. The contact hole 9c is formed in the insulating films 13 and 16. Here, the first capacitor electrode 12c, the insulating film 13, and the second capacitor electrode 15d form a first capacitor 2a. The second capacitor electrode 15d, the insulating film 16, and the third capacitor electrode 17d form a second capacitor 2b. The first capacitor 2a overlaps with the second capacitor 2b, whereby the capacitance can be increased with a small area. The second black matrix layer 17b covers a step formed by the second capacitor electrode 15d. Although FIG. 1 illustrates the structure in which the wiring 12b serving as a scan signal line and the wiring 12d serving as a capacitor line are arranged alternately, the pixel structure of the display device that is one embodiment of the present invention is not limited thereto. The wiring 12b serving as a scan signal line and the wiring 12d serving as a capacitor line are not necessarily arranged alternately.

The first conductive film that is included in the bottom gate electrode 12a and the like can be formed over the base film 11 in the following manner: a conductive film is formed by a sputtering method, a vacuum evaporation method, or the like using any of metal materials such as Mo, Ti, Cr, Ta, W, Al, Cu, Nd, Sc, and Ni; a mask is formed over the conductive film by a photolithography method; and the conductive film is etched using the mask. As the base film, a layer of a nitride of any of the above metal materials may be used for the purpose of improving adhesion between the bottom gate electrode 12a and the glass substrate 10. Note that the first conductive film may be formed with either a single layer or a stack of layers.

Note that side surfaces of the first conductive film are preferably tapered. This is in order not to separate the insulating film 13 and the like which are formed over the bottom gate electrode 12a at a step portion of the bottom gate electrode 12a in later steps. In order to taper the side surfaces of the bottom gate electrode 12a, etching may be performed while the resist mask is made to recede.

The insulating films 13 and 16 can be formed with a single layer or a stack of layers using a silicon nitride film, a silicon nitride oxide film, and/or a silicon oxynitride film by a CVD method.

The source electrode and the drain electrode can be formed in the following manner: a conductive film is formed using any of metal materials of Al, Cu, Ti, Nd, Sc, Mo, Cr, Ta, Ni, and W; a mask is formed over the conductive film by a photolithography method; and the conductive film is etched using the mask. Note that the source electrode and the drain electrode may be formed with either a single layer or a stack of layers.

The first to third black matrix layers are formed of metal, and can be formed using any of metal materials of Ti, Cr, Al, Ta, Mo, and Ni, for example. Note that the first to third black matrix layers may each be formed with a single layer or a stack of layers.

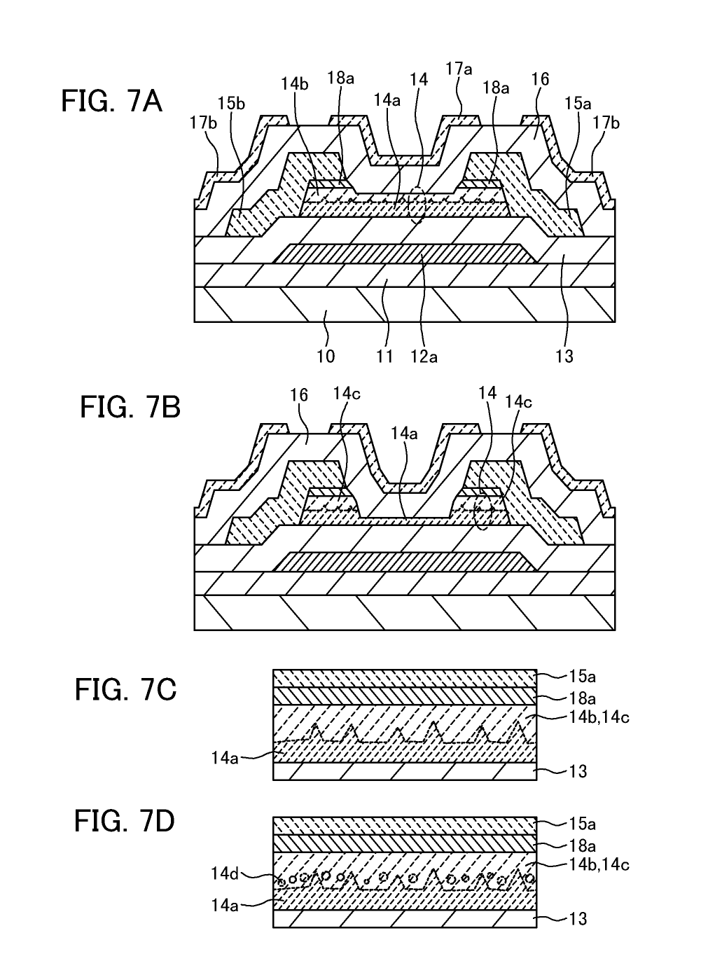

Any of an amorphous semiconductor layer, a microcrystalline semiconductor layer, and a crystalline semiconductor layer may be used for the semiconductor layer 14. Two examples of the semiconductor layer 14 are illustrated in FIGS. 7A and 7B. FIG. 7A is a cross-sectional view illustrating a thin film transistor in which the semiconductor layer 14 includes a microcrystalline silicon region 14a and an amorphous silicon region 14b. FIG. 7B is a cross-sectional view illustrating a thin film transistor in which the semiconductor layer 14 includes the microcrystalline silicon region 14a and a pair of amorphous silicon regions 14c.

As illustrated in FIG. 7A, the microcrystalline silicon region 14a is formed over the insulating film 13, and the amorphous silicon region 14b is formed over the microcrystalline silicon region 14a. Impurity silicon films 18a are formed over the amorphous silicon region 14b.

FIGS. 7C and 7D are enlarged views each illustrating a portion between the insulating film 13 and the source electrode 15a in FIG. 7A. As illustrated in FIG. 7C, a portion of the microcrystalline silicon region 14a which is close to the amorphous silicon region 14b has projections and depressions, and each of the projections has a shape (a conical or pyramidal shape) in which the tip portion gets sharper from the insulating film 13 side toward the impurity silicon film 18a side (the tip portion of the projected portion is acute). Note that the microcrystalline silicon region 14a may have a projected shape (an inverted conical or pyramidal shape) whose width gets broader from the insulating film 13 side toward the impurity silicon film 18a side.

When the thickness of the microcrystalline silicon region 14a, i.e., a distance between the tip portion of the projection (the projected portion) of the microcrystalline silicon region 14a and an interface with the insulating film 13 is set to greater than or equal to 5 nm and less than or equal to 150 nm, the on-state current of the thin film transistor can be increased.

The amorphous silicon region 14b preferably includes an amorphous semiconductor containing nitrogen. Nitrogen included in the amorphous semiconductor containing nitrogen may exist, for example, as an NH group or an NH₂ group. As the amorphous semiconductor, amorphous silicon can be used.

The amorphous silicon film containing nitrogen is a semiconductor having a less amount of the defect absorption spectrum and lower energy at an Urbach edge, which is measured by a constant photocurrent method (CPM) or photoluminescence spectroscopy, as compared to a general amorphous semiconductor. That is, as compared to a conventional amorphous semiconductor, amorphous silicon containing nitrogen is a well-ordered semiconductor which has fewer defects and a steep tail of a level at a band edge in the valence band. Since amorphous silicon containing nitrogen has a steep tail of a level at a band edge in the valence band, the band gap gets wider and tunnel current does not easily flow. Therefore, when the amorphous silicon region 14b containing nitrogen is provided between the microcrystalline silicon region 14a and the impurity silicon film 18a, the off-state current of the thin film transistor can be reduced. In addition, when the amorphous silicon containing nitrogen is provided, the on-state current and the field-effect mobility can be increased.

Further, a peak region of a spectrum of the amorphous silicon containing nitrogen that is obtained by low-temperature photoluminescence spectroscopy is greater than or equal to 1.31 eV and less than or equal to 1.39 eV. Note that a peak region of a spectrum of microcrystalline silicon that is obtained by low-temperature photoluminescence spectroscopy is greater than or equal to 0.98 eV and less than or equal to 1.02 eV. Accordingly, amorphous silicon containing nitrogen is different from microcrystalline silicon.

Further, as illustrated in FIG. 7D, a silicon crystal grain 14d whose grain diameter is greater than or equal to 1 nm and less than or equal to 10 nm, preferably greater than or equal to 1 nm and less than or equal to 5 nm may be included in the amorphous silicon region 14b, so that the on-state current and the filed-effect mobility can be further increased.

Since the portion of the microcrystalline silicon region 14a which is close to the amorphous silicon region 14b has the conical or pyramidal shape or the inverted conical or pyramidal shape, resistance in a vertical direction (film thickness direction) at the time when voltage is applied between the source electrode and the drain electrode in an on state, i.e., the resistance of the amorphous silicon region 14b can be lowered. Further, tunnel current does not easily flow because amorphous silicon containing nitrogen that is a well-ordered semiconductor having few defects and a steep tail of a level at a band edge in the valence band is provided between the microcrystalline silicon region 14a and the impurity silicon film 18a. Thus, in the thin film transistor described in this embodiment, the on-state current and the field-effect mobility can be increased and the off-state current can be reduced.

The impurity silicon films 18a are formed of amorphous silicon to which phosphorus is added, microcrystalline silicon to which phosphorus is added, or the like. Alternatively, the impurity silicon films 18a can have a stacked-layer structure of amorphous silicon to which phosphorus is added and microcrystalline silicon to which phosphorus is added. Note that, in the case where a p-channel thin film transistor is formed as the thin film transistor, the impurity silicon films 18a are formed of microcrystalline silicon to which boron is added, amorphous silicon to which boron is added, or the like.

The impurity silicon films 18a are formed in a treatment chamber of the plasma CVD apparatus, using plasma generated by glow discharge with the use of a mixture of a deposition gas containing silicon, hydrogen, and phosphine (diluted with hydrogen or silane) as a source gas. The deposition gas containing silicon is diluted with hydrogen, in formation of amorphous silicon to which phosphorus is added or microcrystalline silicon to which phosphorus is added. In the case of manufacturing a p-channel thin film transistor, the impurity silicon films 18a may be formed using plasma generated by glow discharge using diborane instead of phosphine.

The source electrode 15a and the drain electrode 15b are formed over the impurity silicon films 18a. The source electrode 15a and the drain electrode 15b are formed in such a manner that a conductive film is formed over the impurity silicon films 18a and etched using a mask.

Part of the impurity silicon film and part of the amorphous silicon region are etched, so that the pair of impurity silicon films 18a functioning as a source region and a drain region is formed, and the amorphous silicon region having a depressed portion is formed (see FIG. 7A).

The insulating film 16 is formed over the source electrode 15a, the drain electrode 15b, the amorphous silicon region 14b, and the insulating film 13. The top gate electrode 17a and the second black matrix layer 17b are formed over the insulating film 16.

As the semiconductor layer 14, the one illustrated in FIG. 7B may also be used. Specifically, part of an impurity silicon film, part of an amorphous silicon region, and part of a microcrystalline silicon region are etched, so that a pair of impurity silicon films 18a functioning as the source region and the drain region, a pair of amorphous silicon regions 14c, and the microcrystalline silicon region 14a are formed. Here, the amorphous silicon region 14c is etched so that the microcrystalline silicon region 14a is exposed. Thus, in a region where the semiconductor layer 14 is covered with the source electrode 15a and the drain electrode 15b, the microcrystalline silicon region 14a and the amorphous silicon region 14c are stacked. On the other hand, in a region overlapping with the top gate electrode 17a, where the semiconductor layer 14 is not covered with the source electrode 15a and the drain electrode 15b, the microcrystalline silicon region 14a is exposed.

The top layout of a pixel portion needs to be determined in consideration of various factors; thus, FIG. 1, FIG. 2, FIG. 3, FIG. 4, FIG. 5, FIG. 6, and FIGS. 7A to 7D are merely an example of a display device of one embodiment of the present invention, and one embodiment of the present invention is not limited thereto.

As one factor to be taken into consideration, the accuracy of alignment in processing in a manufacturing process is given.

In a manufacturing process of a semiconductor device, a photolithography method is frequently used. In a photolithography method, light exposure is an indispensable step; when a substrate is moved, the misalignment of a stage used in light exposure might be generated. Therefore, an appropriate margin needs to be provided in the layout.

On the other hand, the accuracy of light exposure also needs to be taken into consideration. The accuracy of light exposure depends on the thickness of a resist mask, the photosensitivity of a resist material, the wavelength of light used in light exposure, and the accuracy of an optical system.

Since a substrate is placed under circumstances at various temperatures in a manufacturing process of a semiconductor device, thermal expansion (or negative thermal expansion) of the substrate occurs depending on the temperature change. Therefore, the layout needs to be determined in consideration of thermal expansion (or negative thermal expansion) depending on the material of the substrate.

In order to prevent generation of defective contact resistance, it is preferable that an edge portion of the following-mentioned wiring or the like is not located in a contact hole which is provided for establishing electrical continuity between wirings formed of the same layer, wirings formed of different layers, semiconductor layers, a semiconductor layer and a wiring, or a wiring and a wiring formed on another substrate. That is, the layout is determined so that the edge portion thereof is not located in the contact hole and a distance between the edge portion of the contact hole and the edge portion of the wiring is at least approximately the minimum feature size (exposure limit), whereby the occurrence of defective contact resistance can be suppressed. Accordingly, products can be manufactured with high yield.

However, this does not mean that the layout is determined in consideration of only the accuracy of alignment in processing. The electric characteristics of a transistor, the display characteristics required for a display device, the countermeasure against electrostatic discharge (ESD) in a manufacturing process, the yield, and the like also need to be taken into consideration.

For example, the shorter the channel length of a transistor is, the larger the on-state current becomes; therefore, when the on-state current needs to be high, the channel length of a transistor may be about the minimum feature size (exposure limit).

The width of the wiring is made sufficiently large so as to prevent excess wiring resistance. Note that the distance between wirings is set so that a short circuit does not occur due to particles generated in a manufacturing process and interference of signals (such as crosstalk) between a plurality of wirings formed of different layers does not occur.

It is preferable that the top layout design of the pixel portion be determined so that a pattern which is likely to cause electric field concentration is not selected in order to prevent electrostatic breakdown in a manufacturing process. For example, the top layout is preferably designed so that the length of the wiring led is short in order to prevent electrostatic breakdown between the patterns caused by static electricity due to an antenna effect in plasma processing. In the case where the length of the wiring led is long, a short-circuit ring is provided on the periphery of the wirings so that the wiring patterns have the same potential; thus, electrostatic breakdown between the patterns can be prevented. Note that the short-circuit ring may be cut when the substrate is cut or assembled.

The layout is determined so that the plurality of layers overlap with each other. For example, the layout is determined as follows: in the case where one portion and a light-blocking layer overlap with each other for light blocking, the critical dimension (CD) loss, the accuracy of light exposure, and the accuracy of alignment in processing are taken into consideration so that light blocking for this portion can be performed sufficiently. With such layout, light blocking can be achieved with a structure in which one portion and a light-blocking layer overlap with each other in the resulting product.

According to this embodiment, the top gate electrode 17a is formed of the first black matrix layer, and the top gate electrode 17a overlaps with the semiconductor layer 14. Therefore, unintended light from the outside can be prevented from entering the semiconductor layer 14 of the thin film transistor.

In addition, according to this embodiment, since the second black matrix layer is formed so as to surround the top gate electrode, unintended light from the outside can be prevented from entering the semiconductor layer 14, and light leakage due to misalignment between the TFT substrate and the counter substrate can also be prevented.

### Embodiment 2

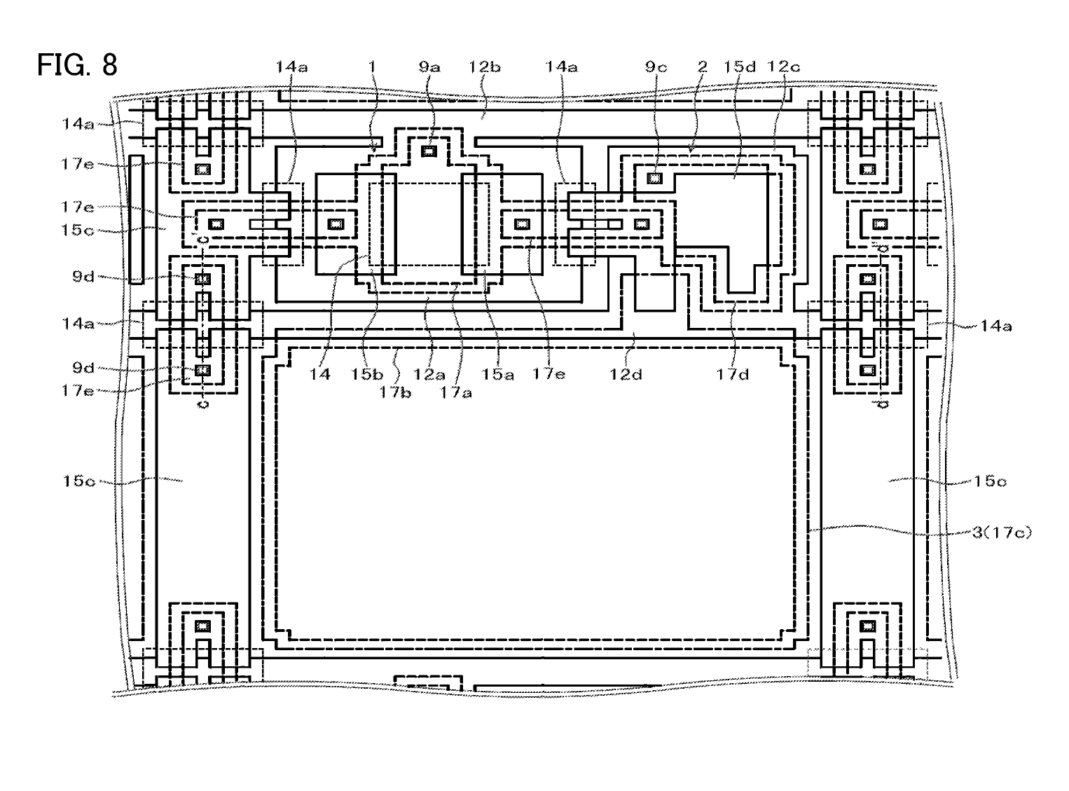

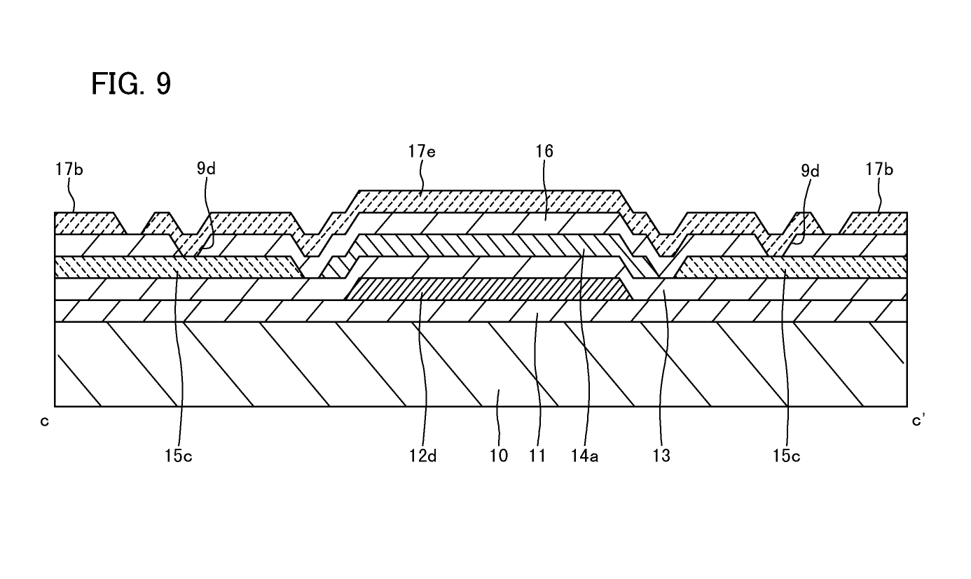

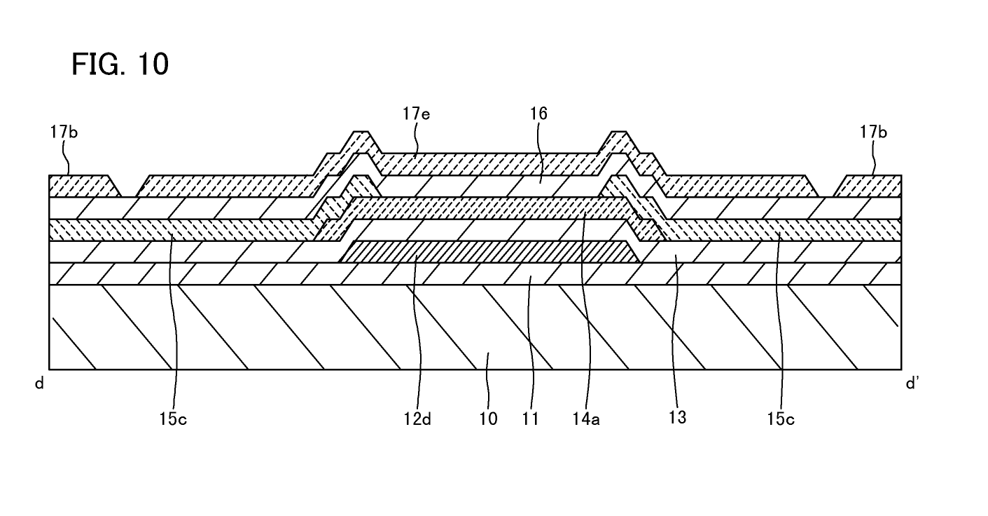

A liquid crystal display device according to one embodiment of the present invention will be described with reference to FIG. 8, FIG. 9, and FIG. 10. Note that in this embodiment, portions which are different from those of Embodiment 1 will be described. The same portions as those in FIG. 1, FIG. 2, FIG. 3, FIG. 4, FIG. 5, FIG. 6, and FIGS. 7A to 7D are denoted by the same reference numerals in FIG. 8, FIG. 9, and FIG. 10.

In FIG. 9 and FIG. 10, the wiring 12d formed of the first conductive film serves as a capacitor line, and the wiring 15c formed of the second conductive film serves as a video signal line.

A parasitic capacitance is generated in an intersection portion of the video signal line (the wiring 15c) and the capacitor line (the wiring 12d) in FIG. 1, which causes delay of a video signal. Therefore, in this embodiment, the wiring 15c (the video signal line) is divided in the intersection portion of the wiring 12d (the capacitor line) and the wiring 15c (the video signal line) as illustrated in FIG. 9. The divided wirings 15c (the video signal line) are electrically connected to each other using a wiring 17e formed of a fourth black matrix layer. In order to further reduce the parasitic capacitance between the wiring 12d and the wiring 17e (the fourth black matrix layer), a semiconductor layer 14a is provided between the wiring 12d (the capacitor line) and the wiring 17e (the fourth black matrix layer) with the insulating films 13 and 16 provided between the semiconductor layer 14a and the wiring 12d and between the semiconductor layer 14a and the wiring 17e, respectively, whereby a distance between the wiring 12d and the wiring 17e in the intersection portion is increased.

A problem of a parasitic capacitance in an intersection portion of wirings is described. Not only the parasitic capacitance in the above intersection portion between the wirings but also a parasitic capacitance in an intersection portion of other wirings (not illustrated) causes a problem. For example, there is a problem of delay of a selection signal due to a parasitic capacitance between the video signal line and a selection signal line (a gate electrode line). The parasitic capacitance is generated in an intersection portion of the video signal line and the selection signal line, and influence of CR delay is increased as a selection signal which is input from an input terminal to the selection signal line becomes more distant from the input terminal, so that the waveform of the selection signal is distorted. As a result, a voltage value which is enough to select a desired pixel by the selection signal cannot be obtained, and a correct signal cannot be transmitted to the pixel, resulting in a lack of a charge period and deterioration in image quality.

In addition, since the video signal lines intersects (extends beyond) the selection signal line and the capacitor line alternately, the parasitic capacitances at the intersection portions with the selection signal line and the capacitor line cause CR delay in the signal which is to be input to the video signal line, thereby causing the distortion of the waveform of the video signal. As a result, there is not enough charge capacity (current), so that the image quality deteriorates. In this manner, when an intersection portion of wirings in which a parasitic capacitance is desirably reduced has a structure similar to that in FIG. 9, the parasitic capacitance between the wirings can be reduced.

The intersection portion of the video signal line (the wiring 15c) and the capacitor line (the wiring 12d) is described below in detail. In FIG. 9 and FIG. 10, the wiring 12d is formed over the base film 11. The wiring 12d serving as a capacitor line is formed of the first conductive film. The insulating film 13 is formed over the wiring 12d and the base film 11, and the semiconductor layer 14a is formed over the insulating film 13. The semiconductor layer 14a is formed using the same layer as the semiconductor layer 14 illustrated in FIG. 8. The wiring 15c serving as a video signal line is formed over the insulating film 13 and the semiconductor layer 14a. The wiring 15c is formed of the second conductive film. The insulating film 16 is formed over the wiring 15c, the semiconductor layer 14a, and the insulating film 13. A contact hole 9d is formed in the insulating film 16. The wiring 17e formed of the fourth black matrix layer is formed in the contact hole 9d and over the insulating film 16. Accordingly, the divided video signal line (the wiring 15c) is electrically connected using the wiring 17e. The second black matrix layer 17b is formed over the insulating film 16 so as to surround the wiring 17e. The second black matrix layer 17b is electrically isolated from the wiring 17e. The fourth black matrix layer is formed using the same layer as the first to third black matrix layers.

An intersection portion of the video signal line (the wiring 15c) and a scan signal line (the wiring 12b) illustrated in FIG. 8 also has the same structure to reduce a parasitic capacitance. That is, in a region where the wiring 15c intersects the wiring 12b, the wiring 15c (the video signal line) is divided, and the divided wirings 15c are electrically connected to each other using the wiring 17e formed of the fourth black matrix layer. In order to further reduce the parasitic capacitance between the wiring 12b and the wiring 17e (the fourth black matrix layer), the semiconductor layer 14a is provided between the wiring 12b and the wiring 17e (the fourth black matrix layer) with the insulating films 13 and 16 provided between the semiconductor layer 14a and the wiring 12b and between the semiconductor layer 14a and the wiring 17e, respectively, whereby a distance between the wiring 12b and the wiring 17e in the intersection portion is increased.

In addition, part of a portion where the drain electrode 15b and the bottom gate electrode 12a overlap with each other illustrated in FIG. 8 has the same structure to reduce a parasitic capacitance. That is, over part of the bottom gate electrode 12a, the drain electrode 15b and the wiring 15c (the video signal) are separated from each other, and the separated wirings are connected using the wiring 17e formed of the fourth black matrix layer. In order to further reduce the parasitic capacitance between the bottom gate electrode 12a and the wiring 17e (the fourth black matrix layer), the semiconductor layer 14a is provided between the bottom gate electrode 12a and the wiring 17e (the fourth black matrix layer) with the insulating films 13 and 16 provided between the semiconductor layer 14a and the bottom gate electrode 12a and between the semiconductor layer 14a and the wiring 17e, respectively, whereby a distance between the bottom gate electrode 12a and the wiring 17e in part of the portion where the bottom gate electrode 12a and the wiring 17e overlap with each other is increased. Note that in this embodiment, although the portion where the drain electrode 15b and the bottom gate electrode 12a overlap with each other also has the structure that reduces the parasitic capacitance, the semiconductor layer 14a is not necessarily provided in the case where the distance between the video signal line (the wiring 15c) and the drain electrode 15b of the thin film transistor is short and thus influence due to the parasitic capacitance does not cause an adverse influence.

In addition, part of a portion where the source electrode 15a and the bottom gate electrode 12a overlap with each other illustrated in FIG. 8 has the same structure to reduce a parasitic capacitance. That is, over part of the bottom gate electrode 12a, the source electrode 15a and the second capacitor electrode 15d are separated from each other, and the separated wirings are connected using the wiring 17e formed of the fourth black matrix layer. In order to further reduce the parasitic capacitance between the bottom gate electrode 12a and the wiring 17e (the fourth black matrix layer), the semiconductor layer 14a is provided between the bottom gate electrode 12a and the wiring 17e (the fourth black matrix layer) with the insulating films 13 and 16 provided between the semiconductor layer 14a and the bottom gate electrode 12a and between the semiconductor layer 14a and the wiring 17e, respectively, whereby a distance between the bottom gate electrode 12a and the wiring 17e in part of the portion where the bottom gate electrode 12a and the wiring 17e overlap with each other is increased. Note that in this embodiment, although the portion where the source electrode 15a and the bottom gate electrode 12a overlap with each other also has the structure that reduces the parasitic capacitance, the semiconductor layer 14a is not necessarily provided in the case where the distance between the second capacitor electrode 15d and the source electrode 15a of the thin film transistor is short and thus influence due to the parasitic capacitance does not cause an adverse influence.

According to this embodiment, the parasitic capacitance is reduced in the intersection portion of the video signal line (the wiring 15c) and the scan signal line (the wiring 12b), the intersection portion of the video signal line (the wiring 15c) and the capacitor line (the wiring 12d), or the portions where the bottom gate electrode 12a and the source and drain electrodes 15a and 15b overlap with each other, whereby a liquid crystal display device which is capable of operating at high speed can be manufactured.

### Embodiment 3

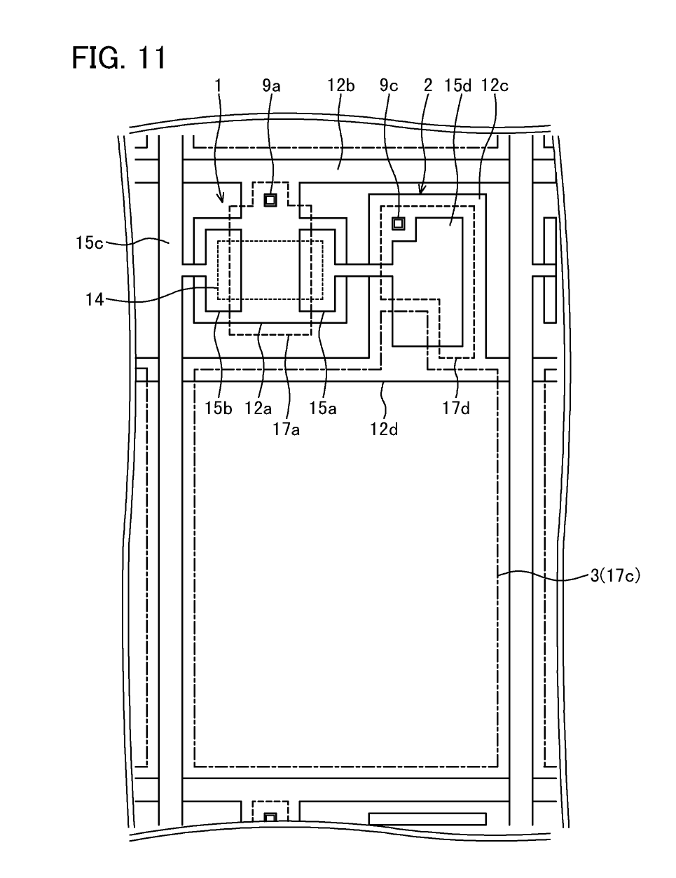

A liquid crystal display device according to one embodiment of the present invention will be described with reference to FIG. 11. Note that in this embodiment, a portion which is different from that of Embodiment 1 is described. The same portions as those in FIG. 1 are denoted by the same reference numerals in FIG. 11.

The second black matrix layer 17b is not provided in this embodiment, whereas the second black matrix layer 17b is provided over the insulating film 16 so as to surround the third capacitor electrode 17d in Embodiment 1.

This application is based on Japanese Patent Application serial no. 2011-116174 filed with Japan Patent Office on May 24, 2011, the entire contents of which are hereby incorporated by reference.

What is claimed is:

1. A semiconductor device comprising:
a transistor comprising a bottom gate electrode, a top gate electrode, a source electrode, a drain electrode, and a first semiconductor layer provided between the bottom gate electrode and the top gate electrode,
wherein the top gate electrode is formed of a first black matrix layer,
wherein the top gate electrode overlaps with the first semiconductor layer, and
wherein the bottom gate electrode is electrically connected to the top gate electrode.

2. The semiconductor device according to claim 1,
wherein the source electrode covers first part of the first semiconductor layer, and
wherein the drain electrode covers second part of the first semiconductor layer.

3. The semiconductor device according to claim 1, wherein the bottom gate electrode has a larger area than the first semiconductor layer.

4. The semiconductor device according to claim 1, further comprising a second black matrix layer surrounding the top gate electrode,
wherein the second black matrix layer is electrically isolated from the top gate electrode, and
wherein the second black matrix layer and the first black matrix layer are formed of the first same film.

5. The semiconductor device according to claim 4, further comprising:
a first capacitor comprising a first capacitor electrode, a first insulating film, and a second capacitor electrode; and
a second capacitor comprising the second capacitor electrode, a second insulating film, and a third capacitor electrode,
wherein the first capacitor and the second capacitor overlap with each other,
wherein the first capacitor electrode and the third capacitor electrode are electrically connected to each other,
wherein the first capacitor electrode and the bottom gate electrode are formed of the second same film,
wherein the third capacitor electrode is a third black matrix layer, and
wherein the third black matrix layer and the first black matrix layer are formed of the first same film.

6. The semiconductor device according to claim 5,
wherein the second black matrix layer surrounds the third capacitor electrode, and
wherein the second black matrix layer is electrically isolated from the third capacitor electrode.

7. The semiconductor device according to claim 5, further comprising:
a first wiring electrically connected to the third capacitor electrode through the first capacitor electrode; and
a second wiring connected to one of the source electrode and the drain electrode,
wherein a second semiconductor layer is located in an intersection portion of the first wiring and the second wiring,
wherein the first wiring and the bottom gate electrode are included in the first same layer,
wherein the second wiring and the one of the source electrode and the drain electrode are included in the second same layer, and
wherein the first semiconductor layer and the second semiconductor layer are formed of the third same film.

8. A semiconductor device comprising:
a transistor comprising:
a bottom gate electrode;
a first insulating film over the bottom gate electrode;
a first semiconductor layer over the first insulating film;
a source electrode and a drain electrode each of which electrically connected to the first semiconductor layer;
a second insulating film over the first semiconductor layer; and
a top gate electrode over the second insulating film, the top gate electrode being formed of a first black matrix layer; and
a second black matrix layer over the second insulating film,
wherein the top gate electrode overlaps with the first semiconductor layer,
wherein the second black matrix layer surrounds the top gate electrode,
wherein the second black matrix layer is electrically isolated from the top gate electrode, and
wherein the bottom gate electrode is electrically connected to the top gate electrode.

9. The semiconductor device according to claim 8,
wherein the source electrode covers first part of the first semiconductor layer,
wherein the drain electrode covers second part of the first semiconductor layer,
wherein the source electrode and the drain electrode are located over the first semiconductor layer and the first insulating film, and below the second insulating film.

10. The semiconductor device according to claim 8, wherein the bottom gate electrode has a larger area than the first semiconductor layer.

11. The semiconductor device according to claim 8,
wherein the second black matrix layer and the first black matrix layer are formed of the first same film.

12. The semiconductor device according to claim 8, further comprising:
a first capacitor comprising a first capacitor electrode, the first insulating film, and a second capacitor electrode; and
a second capacitor comprising the second capacitor electrode, the second insulating film, and a third capacitor electrode,
wherein the first capacitor and the second capacitor overlap with each other,
wherein the first capacitor electrode and the third capacitor electrode are electrically connected to each other,
wherein the first capacitor electrode and the bottom gate electrode are formed of the second same film,
wherein the third capacitor electrode is a third black matrix layer,
wherein the first black matrix layer, the second black matrix layer, and the third black matrix layer are formed of the first same film, and
wherein the second black matrix layer surrounds the third capacitor electrode and is electrically isolated from the third capacitor electrode.

13. The semiconductor device according to claim 12, further comprising:
a first wiring electrically connected to the third capacitor electrode;
a second wiring connected to one of the source electrode and the drain electrode of the transistor; and
a conductive layer electrically connected to the second wiring,
wherein the first insulating film, a second semiconductor layer, and the second insulating film are located in an intersection portion of wherein the first wiring and the bottom gate electrode are formed of the second same film are included in the first same layer,
wherein the conductive layer is a fourth black matrix layer, and
wherein the fourth black matrix layer and the first black matrix layer are formed of the first same film.

14. The semiconductor device according to claim 13
wherein the first wiring and the bottom gate electrode are included in the first same layer,
wherein the second wiring and the one of the source electrode and the drain electrode are included in the second same layer, and
wherein the first semiconductor layer and the second semiconductor layer are formed of the third same film
